(19) United States
(12) Patent Application Publication
(10) Pub. No.: US 2026/0190216 A1
(43) Pub. Date: Jul. 2, 2026

(54) Display Device

(71) Applicant: LG Display Co., Ltd., Seoul (KR)

(72) Inventor: Taehyung Kim, Paju-si (KR)

(21) Appl. No.: 19/426,717

(22) Filed: Dec. 19, 2025

(30) Foreign Application Priority Data
Dec. 26, 2024 (KR) 10-2024-0196946

(51) Int. Cl. H05K 1/02; G06F 1/16

(52) U.S. Cl. CPC H05K 1/0271; G06F 1/1658; H05K 2201/10128; H05K 2201/10189; H05K 2201/2045

(57) ABSTRACT

Disclosed is a display device, including: a display panel including a plurality of pixels and configured to display an image; a circuit board attached to one surface of the display panel through an adhesive member; a vibration absorbing unit disposed on one surface of the circuit board, spaced apart from the adhesive member on a plane and configured to absorb vibration; and a connector disposed on one surface of the circuit board, and the vibration absorbing unit may include: at least one supporter disposed on one surface of the circuit board; a lower damper disposed on the at least one supporter; and an upper damper disposed on the lower damper.

### CROSS REFERENCE TO RELATED APPLICATIONS

The present application claims priority under 35 U.S.C. § 119(a) to the Republic of Korea Patent Application No. 10-2024-0196946, filed on Dec. 26, 2024, the entire contents of which are hereby expressly incorporated by reference into the present application.

### FIELD

The present disclosure relates to a display device.

### BACKGROUND

As information society has developed, various demands on the display device displaying an image are increasing, and various display devices such as a liquid crystal display (LCD), and an organic light emitting display (OLED) have been utilized.

The images displayed in the display device may be still images or moving images. If the images are moving images, the images may be various kinds such as sports images, game images, movies, and the like. The display device may include a plurality of pixels and a plurality of switching elements for driving the pixels.

### SUMMARY

The technical problem to be solved by the present disclosure is to provide a display device capable of preventing a damage to an adjacent display panel during a transport process of a plurality of display panels.

The technical problem to be achieved by the present disclosure is not limited to the above-mentioned technical problem, and other technical problems that are not mentioned will be inferred from the embodiments provided below.

One embodiment is a display device, including: a display panel including a plurality of pixels and configured to display an image; a circuit board attached to one surface of the display panel through an adhesive member; a vibration absorbing unit disposed on one surface of the circuit board, spaced apart from the adhesive member on a plane and configured to absorb vibration; and a connector disposed on one surface of the circuit board, and the vibration absorbing unit may include: at least one supporter disposed on one surface of the circuit board; a lower damper disposed on the at least one supporter; and an upper damper disposed on the lower damper.

Another embodiment is a display device, including: a display panel including a plurality of pixels and configured to display an image; a circuit board attached to one surface of the display panel through an adhesive member; a connector disposed on one surface of the circuit board; and a vibration absorbing unit disposed on one surface of the connector, spaced apart from the adhesive member on a plane and configured to absorb vibration, and the vibration absorbing unit may include: at least one supporter disposed on a side surface of the connector; a lower damper disposed on the at least one supporter; and an upper damper disposed on the lower damper.

Another embodiment is a display device, including: a display panel including a plurality of pixels, wherein the display device is configured to display an image; a circuit board disposed on the display panel; an adhesive member that attaches a portion of the circuit board to the display panel; a vibration absorbing unit disposed above the circuit board; a connector disposed on one surface of the circuit board; and a connector holder attached to one surface of the connector. In some embodiments, the connector holder is configured to electrically connect the connector to a control circuit. In some embodiments, the adhesive member, the circuit board, the vibration absorbing unit, and the connector are sequentially arranged in a first direction.

Other details of the embodiments are included in the detailed description and the accompanying drawings.

As the display device according to the embodiments of the present disclosure includes a vibration absorbing unit disposed in a vibration transfer path of a display panel, the display device may prevent damage of other adjacent display panels by absorbing vibration transferred to a connector and preventing a rotation or a flip of a connector holder.

The display device according to the embodiments of the present disclosure may reduce defects of a product and improve reliability of a display by preventing damage to a display panel.

However, effects which may be obtained by the present disclosure are not limited to the aforementioned effects, and other technical effects not described above may be evidently understood by a person having ordinary skill in the art to which the present disclosure pertains from the following description.

### BRIEF DESCRIPTION OF THE DRAWINGS

The above and other objects, features, and advantages of the present disclosure will become more apparent to those of ordinary skill in the art by describing exemplary embodiments thereof in detail with reference to the attached drawings, in which:

FIG. 1 is a side view illustrating a display device according to an embodiment.

FIG. 2 is a plan view illustrating a display device according to an embodiment of the present disclosure.

FIG. 3 is a block diagram illustrating a display device according to an embodiment.

FIG. 4 is a view illustrating one example of a vibration absorbing unit in a display device according to an embodiment.

FIG. 5 is a view illustrating another example of a vibration absorbing unit in a display device according to an embodiment.

FIG. 6 is a view illustrating a vibration transfer path in a display device according to an embodiment.

FIG. 7 is a side view illustrating a display device according to another embodiment.

FIG. 8 is a view illustrating a vibration absorbing unit in a display device according to another embodiment.

FIG. 9 is a side view illustrating a display device according to still another embodiment.

FIG. 10 is a side view illustrating a display device according to still another embodiment.

FIG. 11 is a side view illustrating a display device according to still another embodiment.

FIG. 12 is a view illustrating an intensity of vibration energy in a display device in which a vibration absorbing unit is omitted.

FIG. 13 is a view illustrating an intensity of a vibration energy in a display device in which a vibration absorbing unit is included.

FIG. 14 is a view illustrating a transport process of a plurality of display devices.

### DETAILED DESCRIPTION

Hereinafter, embodiments of the disclosure will be described with reference to the drawings. In this specification, when it is mentioned that a component (or, an area, a layer, a part, etc.) is referred to as being “on”, “connected to” or “combined to” another component, this means that the component may be directly on, connected to, or combined to the other component or a third component therebetween may be present.

Like reference numerals refer to like elements. Additionally, in the drawings, the thicknesses, proportions, and dimensions of components are exaggerated for effective description. “And/or” includes all of one or more combinations defined by related components.

In addition, terms such as “below”, “the lower side”, “on”, and “the upper side” are used to describe a relationship of configurations shown in the drawing. The terms are described as a relative concept based on a direction shown in the drawing.

In various embodiments of the disclosure, the term “include,” “comprise,” “including,” or “comprising,” specifies a property, a fixed number, a step, a process, an element and/or a component, or a combination thereof, but does not exclude presence or addition of other properties, fixed numbers, steps, processes, elements and/or components, or a combination thereof.

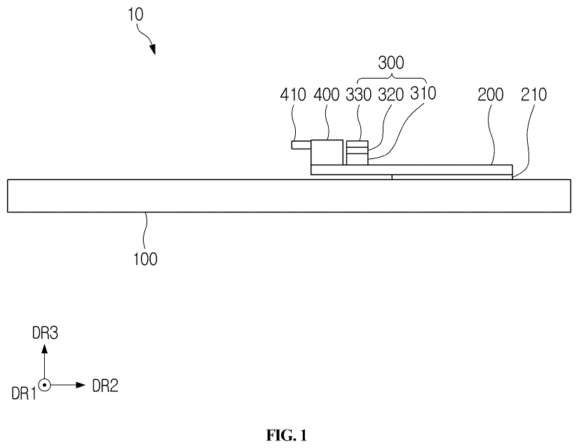

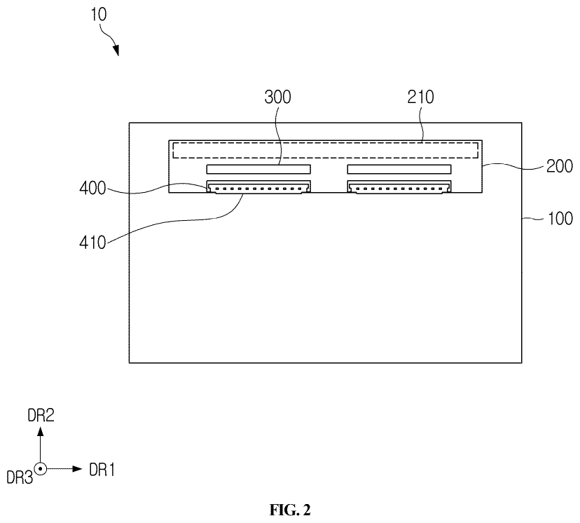

FIG. 1 is a side view illustrating a display device according to an embodiment, and FIG. 2 is a plan view illustrating a display device according to an embodiment of the present disclosure.

Referring to FIGS. 1 and 2, the display device 10 may be applied to a portable electronic device such as a mobile phone, a smart phone, a tablet personal computer, a mobile communication terminal, an electronic organizer, an e-book reader, a portable multimedia player (PMP), a navigation apparatus, an ultra-mobile PC (UMPC), and the like. For example, the display device 10 according to the present embodiment may be applied as a display unit of a television, a notebook computer, a monitor, a billboard, an Internet of things (IoT) device, and the like. As another example, the display device 10 according to the present embodiment may be applied to various wearable devices, for example, such as smart watches, watch phones, glass-like displays, head-mounted displays (HMDs), and the like.

The display device 10 may include a display panel 100, a circuit board 200, a vibration absorbing unit 300, and a connector 400.

The display panel 100 may emit light on a plane which includes a first direction DR1 and a second direction DR2, and may have a thickness in a third direction DR3. The display panel 100 may include a plurality of pixels which displays an image. Each of the plurality of pixels may emit light from a light emitting region or an opening region. For example, the pixel may include a pixel circuit including switching elements, a pixel defining layer defining the light emitting region, and a self-light emitting element.

For example, the self-light emitting element may include at least one among an organic light emitting diode including an organic light emitting layer, a quantum-dot light emitting diode (LED) including a quantum-dot light emitting layer, an inorganic light emitting diode (LED) including an inorganic semiconductor, and a micro-light emitting diode (LED) or a nano-light emitting diode (LED), but is not limited thereto.

The circuit board 200 may be attached to one surface of the display panel 100 through an adhesive member 210. The adhesive member 210 may include an adhesive or a double-sided adhesive tape having a relatively thin thickness. One surface of the display panel 100 to which the circuit board 200 is attached may be opposite to another surface thereof in which light of the display panel 100 is emitted. The circuit board 200 may be a printed circuit board electrically connected to the display panel 100. For example, the display device 10 may further include a flexible film (not illustrated) electrically connected between the circuit board 200 and the display panel 100, and a control circuit board (not illustrated) in which control components and various electronic devices are mounted. The circuit board 200 may include signal lines which electrically connect the control circuit board and the flexible film to each other.

The circuit board 200 may include a first portion attached to the adhesive member 210, a second portion directly supporting the vibration absorbing unit 300, and a third portion directly supporting the connector 400. Here, the first to third portions of the circuit board 200 are not illustrated in the drawings. The second portion and the third portion of the circuit board 200 may not be attached to the adhesive member 210 and may be spaced apart from one surface of the display panel 100.

The vibration absorbing unit 300 may be disposed on one surface of the circuit board 200. The vibration absorbing unit 300 may be disposed between the connector 400 and the adhesive member 210 on a plane. The vibration absorbing unit 300 may not overlap the adhesive member 210 in the third direction DR3 or a thickness direction. The vibration absorbing unit 300 may be spaced apart from the adhesive member 210 in the second direction DR2. As the vibration absorbing unit 300 does not overlap the adhesive member 210 in the thickness direction, vibration in the third direction DR3 of the display panel 100 may not be directly transferred through the adhesive member 210. The vibration in the third direction DR3 of the display panel 100 may be transferred to the adhesive member 210 and the circuit board 200, and may be transferred to the vibration absorbing unit 300 through vibration in the second direction DR2 or a direction opposite the second direction DR2. A resonant frequency of the vibration absorbing unit 300 may be the same as or lower than a resonant frequency of rotation of the connector holder 410. Therefore, the vibration absorbing unit 300 may be disposed in the vibration transfer path of the display panel 100 and may absorb vibration transferred to the connector 400, and may prevent a rotation or a flip of the connector holder 410.

For example, the display device 10 may include a plurality of vibration absorbing units 300 and a plurality of connectors 400, and one vibration absorbing unit 300 may be disposed on one side of one connector 400. Therefore, each of the plurality of vibration absorbing units 300 may absorb vibration transferred to the connector 400 corresponding thereto.

The vibration absorbing unit 300 may include at least one supporter 310, a lower damper 320, and an upper damper 330. The at least one supporter 310 may be disposed on one surface of the circuit board 200. The at least one supporter 310 may be disposed below a first side of the lower damper 320, or below a second side opposite the first side of the lower damper 320. In FIG. 2, when the vibration absorbing unit 300 includes two supporters 310, one supporter 310 may be disposed below a left side of the lower damper 320 and the other supporter 310 may be disposed below a right side of the lower damper 320, thereby the supporters 310 can support the lower damper 320.

For example, the supporter 310 may be formed of a plastic material such as polycarbonate (PC), polyimide (PI), polyethylene naphthalate (PEN), polyethylene terephthalate (PET), polyethersulfone (PES), polyacrylate (PAR), or a fiber reinforced plastic. For example, the supporter 310 may be mounted on one surface of the circuit board 200 through a plastic molding using plastic curing or injection molding. As another example, the supporter 310 may be mounted on one surface of the circuit board 200 in an ultrasonic fusion manner or a thermal fusion manner. As still another example, the supporter 310 may be attached to one surface of the circuit board 200 through an adhesive.

The lower damper 320 may be disposed on at least one supporter 310. The lower damper 320 may include a long side in the first direction DR1, and a short side in the second direction DR2. A length of the lower damper 320 in the first direction DR1 may correspond to a length of the connector 400 in the first direction DR1. A material configuring the lower damper 320 may be different from a material configuring the upper damper 330. As the vibration absorbing unit 300 includes the lower damper 320 and the upper damper 330, each of which including a different material, the vibration absorbing unit 300 may reduce the resonant frequency and absorb vibration transferred to the connector 400.

The lower damper 320 may include a metal material. For example, the lower damper 320 may include at least one among aluminum (Al), molybdenum (Mo), chrome (Cr), gold (Au), silver (Ag), titanium (Ti), nickel (Ni), palladium (Pd), indium (In), neodymium (Nd), and copper (Cu), however, the material configuring the lower damper 320 is not limited thereto. The lower damper 320 may be formed on one surface of the supporter 310 through a plastic molding using plastic curing or injection molding. As another example, the lower damper 320 may be mounted on one surface of the supporter 310 in an ultrasonic fusion manner or a thermal fusion manner. As still another example, the lower damper 320 may be attached to one surface of the supporter 310 through an adhesive.

The upper damper 330 may be disposed on the lower damper 320. A planar shape and a size of the upper damper 330 may be substantially the same as a planar shape and a size of the lower damper 320, however, the planar shape of the upper damper 330 is not limited thereto. The upper damper 330 may include a long side in the first direction DR1, and a short side in the second direction DR2. A length of the upper damper 330 in the first direction DR1 may correspond to the length of the connector 400 in the first direction DR1. A material configuring the upper damper 330 may be different from the material configuring the lower damper 320. As the vibration absorbing unit 300 includes the lower damper 320 and the upper damper 330, each of which including a different material, the vibration absorbing unit 300 may reduce the resonant frequency and absorb vibration transferred to the connector 400.

The upper damper 330 may include at least one among a polymer tape, a damping tape, an elastic polymer, silicon, and rubber. For example, the upper damper 330 may include at least one among ultra-high-molecular-weight polyethylene (UHMWPE), high-density polyethylene (HDPE), polypropylene (PP), polyetherimide (PEI), fluorinated ethylene propylene (FEP), polytetrafluoroethylene (PTFE), methyl fluoroacetate (MFA), perfluoroalkoxy alkane (PFA).

The connector 400 may be disposed on an edge on one surface of the circuit board 200. A first edge of the circuit board 200 may be attached to the display panel 100 by the adhesive member 210, and a second edge opposite the first edge of the circuit board 200 may support the connector 400. The connector 400 may electrically connect the circuit board 200 and the control circuit board (not illustrated) to each other. The connector 400 may be spaced apart from the adhesive member 210, with the vibration absorbing unit 300 interposed therebetween. The connector 400 may be protected from the vibration transferred from the display panel 100 by the vibration absorbing unit 300. The connector 400 may include a first side surface facing the vibration absorbing unit 300 and a second side surface opposite the first side surface.

The connector holder 410 may be disposed on the second side surface of the connector 400. The connector holder 410 may be fixed by accommodating a cable pin or a cable terminal connecting the control circuit board (not illustrated) and the connector 400 to each other. One end of the connector holder 410 may be fixed to the connector 400, and the other end opposite the one end of the connector holder 410 may rotate about the one end of the connector holder 410. In FIG. 1, the connector holder 410 headed toward a direction opposite the second direction DR2 of the connector 400 may rotate in the third direction DR3 by receiving the vibration. In the transport process of the plurality of display panels 100, when the vibration transferred from the display panel 100 reaches the connector 400, the connector holder 410 rotates and damages the other display panel 100 adjacent thereto. Therefore, as the vibration absorbing unit 300 is disposed in the vibration transfer path of the display panel 100, the vibration absorbing unit 300 may absorb the vibration transferred to the connector 400, and may prevent damage to the other adjacent display panel 100 by preventing a rotation or a flip of the connector holder 410.

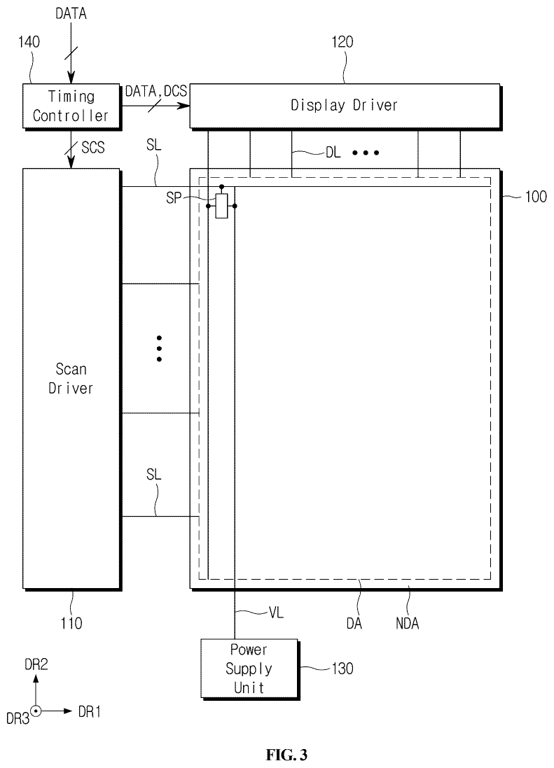

FIG. 3 is a block diagram illustrating the display device according to an embodiment.

Referring to FIG. 3, the display panel 100 may include a display region DA and a non-display region NDA. The display region DA may include a plurality of pixels SP, a power supply line VL connected to the plurality of pixels SP, a scan line SL, and a data line DL.

Each of the pixels SP may be connected to the scan line SL, the data line DL, and a power supply line VL. Each of the pixels SP may include a transistor, a light emitting diode, and a capacitor.

The scan lines SL may extend in the first direction DR1, and may be spaced from each other in the second direction DR2 intersecting the first direction DR1. The scan lines SL may sequentially supply the scan signals to the plurality of pixels SP.

The data lines DL may extend in the second direction DR2, and may be spaced from each other in the first direction DR1. The data lines DL may supply the data voltage to the pixels SP. The data voltage may determine luminance of the pixel SP.

The power supply lines VL may extend in the second direction DR2, and may be spaced apart from each other in the first direction. The power supply lines VL may supply a power supply voltage to the plurality of pixels SP. The power supply voltage may include a driving voltage EVDD, a low potential voltage EVSS, an initialization voltage Vint, a reference voltage Vref, and a bias voltage Vbias, but is not limited thereto.

The scan driver 110 may include a plurality of transistors, and may generate scan signals based on a scan control signal SCS. The scan driver 110 may shift a scan signal using a shift register, and may sequentially supply the shifted scan signals to the scan lines. The scan signals of the scan driver 110 may select the pixels SP to which the data voltage is supplied, and the selected pixels SP may receive the data voltage through the data lines DL. The scan driver 110 may be disposed on one side or both sides of the non-display region DNA in a Gate-In-Panel (GIP) manner.

The display driver 120 may supply a data voltage to the data line DL of the display panel 100. The display driver 120 may be mounted on the flexible film (not illustrated), and may be electrically connected to the data line DL of the display panel 100 through a pad part of the display panel 100. The display driver 120 may be formed as an integrated circuit (IC). For example, the display driver 120 may be attached to one surface of the flexible film in a chip-on-film (COF) manner. The flexible film may include lines electrically connecting the display driver 120 and the display panel 100. One side of the flexible film may be electrically connected to the pad part of the display panel 100, and the other side of the flexible film may be electrically connected to the circuit board 200.

The power supply unit 130 may supply a power supply voltage to the power supply lines VL. The power supply voltage may include a driving voltage EVDD, a low potential voltage EVSS, an initialization voltage Vint, a reference voltage Vref, and a bias voltage Vbias, but is not limited thereto. The power supply unit 130 may generate the driving voltage EVDD and supply the driving voltage EVDD to a driving voltage line, generate the initialization voltage Vint and supply the initialization voltage Vint to an initialization voltage line, generate the bias voltage Vbias and supply the bias voltage Vbias to the bias voltage line, generate the reference voltage Vref and supply the reference voltage Vref to a reference voltage line, and generate the low potential voltage EVSS and supply the low potential voltage EVSS to the low potential line.

The timing controller 140 may receive digital video data DATA and timing signals from a display driving system or a graphic device (not illustrated). The timing controller 140 may generate the data control signal DCS based on the timing signals. The timing controller 140 may supply the digital video data DATA and the data control signal DCS to the display driver 120 to control an operation timing of the display driver 120. The display driver 120 may convert the digital video data DATA into the analog data voltages and supply the analog data voltages to the data lines DL. The timing controller 140 may generate the scan control signal SCS based on the timing signals. The timing controller 140 may supply the scan control signal SCS to the scan driver 220 to control an operation timing of the scan driver 220. The timing controller 140 may vary the driving frequency based on an input frequency received from the display driving system or the graphic device (not illustrated).

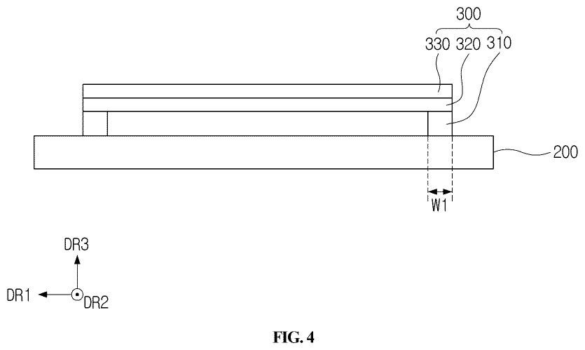

FIG. 4 is a view illustrating one example of the vibration absorbing unit in the display device according to an embodiment.

Referring to FIG. 4, the vibration absorbing unit 300 may be disposed on one surface of the circuit board 200. The resonant frequency of the vibration absorbing unit 300 may be the same as or lower than a resonant frequency of rotation of the connector holder 410. Therefore, the vibration absorbing unit 300 may be disposed in the vibration transfer path of the display panel 100 and may absorb vibration transferred to the connector 400, and may prevent a rotation or a flip of the connector holder 410.

The vibration absorbing unit 300 may include a plurality of supporters 310, the lower damper 320, and the upper damper 330. The plurality of supporters 310 may be disposed below the left side and the right side of the lower damper 320, thereby the supporters 310 may support the lower damper 320. The supporter 310 may have a first width W1 in the first direction DR1.

The lower damper 320 may be disposed on the at least one supporter 310. The lower damper 320 may include the long side in the first direction DR1, and the short side in the second direction DR2. The material configuring the lower damper 320 may be different from the material configuring the upper damper 330. As the vibration absorbing unit 300 includes the lower damper 320 and the upper damper 330, each of which including a different material, the vibration absorbing unit 300 may reduce the resonant frequency and absorb vibration transferred to the connector 400.

The upper damper 330 may be disposed on the lower damper 320. The upper damper 330 may include the long side in the first direction DR1, and the short side in the second direction DR2. The material configuring the upper damper 330 may be different from the material configuring the lower damper 320. As the vibration absorbing unit 300 includes the lower damper 320 and the upper damper 330, each of which including a different material, the vibration absorbing unit 300 may reduce the resonant frequency and absorb vibration transferred to the connector 400.

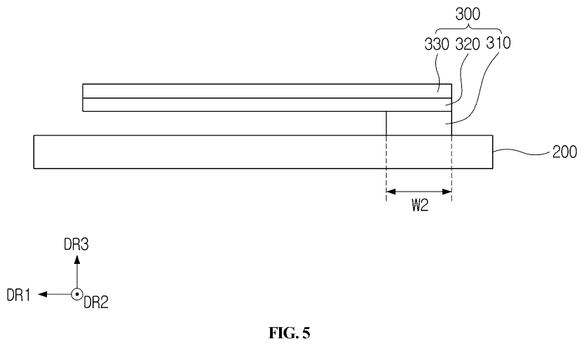

FIG. 5 is a view illustrating another example of the vibration absorbing unit in the display device according to an embodiment. The supporter 310 of the vibration absorbing unit 300 in FIG. 5 has a different configuration from that of the supporter 310 of the vibration absorbing unit 300 in FIG. 4, and thus, the same components as those described above will be briefly described or omitted.

Referring to FIG. 5, the vibration absorbing unit 300 may include the supporter 310, the lower damper 320, and the upper damper 330. The supporter 310 may support a lower portion of one side of the lower damper 320. The supporter 310 may have a second width W2 in the first direction DR1. The second width W2 of the supporter 310 illustrated in FIG. 5 may be greater than the first width W1 of the supporter 310 in FIG. 4. The vibration absorbing unit 300 in FIG. 5 includes the supporter 310 having a relatively greater width, therefore, the vibration absorbing unit 300 may reduce a quantity of the supporter 310.

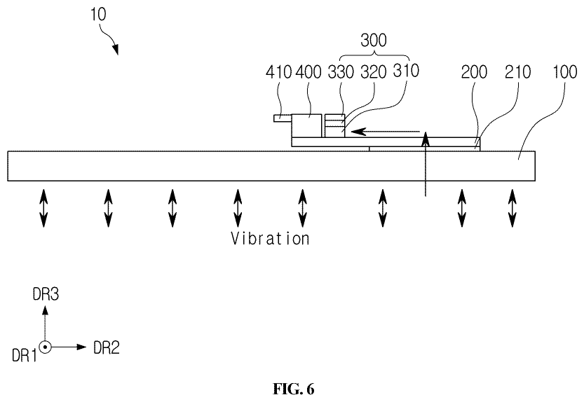

FIG. 6 is a view illustrating the vibration transfer path in the display device according to an embodiment.

Referring to FIG. 6, in the transport process of the plurality of display panels 100 in the second direction DR2 or a direction opposite the second direction DR2, the display panel 100 may vibrate in the third direction DR3. The vibration of the display panel 100 in the third direction DR3 may be transferred to the adhesive member 210 and the circuit board 200, and may be transferred to the vibration absorbing unit 300 through the vibration of the circuit board 200 in the second direction DR2 or a direction opposite the second direction DR2. As the vibration absorbing unit 300 does not overlap the adhesive member 210 in the thickness direction, the vibration in the third direction DR3 of the display panel 100 may not be directly transferred through the adhesive member 210. The resonant frequency of the vibration absorbing unit 300 may be the same as or lower than the resonant frequency of rotation of the connector holder 410.

In the transport process of the plurality of display panels 100, when the vibration transferred from the display panel 100 reaches the connector 400, the connector holder 410 rotates and damages the other display panel 100 adjacent thereto. Therefore, as the vibration absorbing unit 300 is disposed in the vibration transfer path of the display panel 100, the vibration absorbing unit 300 may absorb the vibration transferred to the connector 400, and may prevent damage to the other adjacent display panel 100 by preventing a rotation or a flip of the connector holder 410.

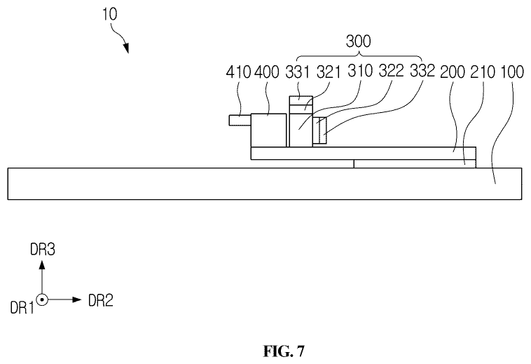

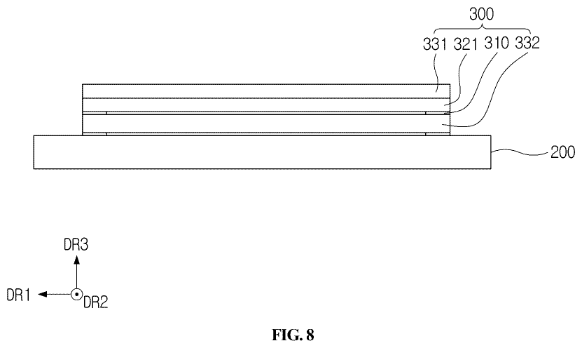

In one embodiment, the connector 400, the vibration absorbing unit 300, and the adhesive unit attaching the circuit board 200 to the display are sequentially arranged along the second direction DR2 in that order. For example, the vibration absorbing unit 300 is placed between the connector 400 and the adhesive so that when the vibration travels from the display towards the connector 400, the vibration absorbing unit 300 can absorb the vibration. The vibration absorbing unit 300 may include a supporter 310 disposed above the circuit board 200, a lower damper 320 disposed on the supporter 310, and an upper damper 330 disposed on the lower damper 320. The materials of the supporter 310, the lower damper 320, and the upper damper 330 may be different. For example, the supporter 310 may comprise a plastic material, the lower damper 320 may comprise a metal material, and the upper damper 330 may comprise at least one of a polymer, silicon, and rubber. FIG. 7 is a side view illustrating a display device according to another embodiment, and FIG. 8 is a view illustrating a vibration absorbing unit in a display device according to another embodiment. The vibration absorbing unit of the display device in FIGS. 7 and 8 has a different configuration from that of the vibration absorbing unit 300 of the display device in FIGS. 4 and 5, and thus, the same components as those described above will be briefly described or omitted.

Referring to FIGS. 7 and 8, the vibration absorbing unit 300 may be disposed on one surface of the circuit board 200. The vibration absorbing unit 300 may be disposed between the connector 400 and the adhesive member 210 on a plane. The vibration absorbing unit 300 may not overlap the adhesive member 210 in the third direction DR3 or the thickness direction. The vibration absorbing unit 300 may be spaced apart from the adhesive member 210 in the second direction DR2.

The vibration absorbing unit 300 may include the supporter 310, a first lower damper 321, a second lower damper 322, a first upper damper 331, and a second upper damper 332. A second lower damper 322 may be disposed on a side surface of the supporter. A second upper damper 332 may be disposed on the second lower damper. In some embodiments, the vibration absorbing unit 300 may be attached to the connector 400. In some embodiments, the vibration absorbing unit 300 may be attached to the circuit board 200. A plurality of supporters 310 may be disposed on one surface of the circuit board 200. The plurality of supporters 310 may be disposed below a first side of the first lower damper 321, and below a second side opposite the first side of the first lower damper 321. As the plurality of supporters 310 are disposed below a left side and a right side of the first lower damper 321, the plurality of supporters 310 may support the lower damper 320. An upper surface of the supporter 310 may support the first lower damper 321 in the third direction DR3. The supporter 310 may be disposed on a side surface of the second lower damper 322. A first side surface of the supporter 310 may support the second lower damper 322 in the second direction DR2. A second side surface of the supporter 310 opposite the first side surface thereof may face the connector 400.

As another example, the supporter 310 may support a left side or a right side of the first lower damper 321 and the second lower damper 322 by reflecting the embodiment of FIG. 5.

The first lower damper 321 may be disposed on at least one supporter 310. The first lower damper 321 may include a long side in the first direction DR1, a short side in the second direction DR2, and a thickness in the third direction DR3. A length of the first lower damper 321 in the first direction DR1 may correspond to the length of the connector 400 in the first direction DR1. A material configuring the first lower damper 321 may be different from a material configuring the first upper damper 331.

The first upper damper 331 may be disposed on the first lower damper 321. A planar shape and a size of the first upper damper 331 may be substantially the same as a planar shape and a size of the first lower damper 321, however, the planar shape of the first upper damper 331 is not limited thereto. The first upper damper 331 may include a long side in the first direction DR1, a short side in the second direction DR2, and a thickness in the third direction DR3. A length of the first upper damper 321 in the first direction DR1 may correspond to the length of the connector 400 in the first direction DR1. A material configuring the first upper damper 331 may be different from a material configuring the first lower damper 321. As the vibration absorbing unit 300 includes the first lower damper 321 and the first upper damper 331, each of which including a different material, the vibration absorbing unit 300 may reduce the resonant frequency and absorb vibration transferred to the connector 400.

The second lower damper 322 may be disposed on a side surface of at least one supporter 310. The second lower damper 322 may include a long side in the first direction DR1, a short side in the third direction DR3, and a thickness in the second direction DR2. A length of the second lower damper 322 in the first direction DR1 may correspond to the length of the connector 400 in the first direction DR1. A material configuring the second lower damper 322 may be different from a material configuring the second upper damper 332.

The second upper damper 332 may be disposed on the second lower damper 322. A planar shape and a size of the second upper damper 332 may be substantially the same as a planar shape and a size of the second lower damper 322, however, the planar shape of the second upper damper 332 is not limited thereto. The second upper damper 322 may include a long side in the first direction DR1, a short side in the third direction DR3, and a thickness in the second direction DR2. A length of the second upper damper 332 in the first direction DR1 may correspond to the length of the connector 400 in the first direction DR1. A material configuring the second upper damper 332 may be different from a material configuring the second lower damper 322. As the vibration absorbing unit 300 includes the second lower damper 322 and the second upper damper 332, each of which including a different material, the vibration absorbing unit 300 may reduce the resonant frequency and absorb vibration transferred to the connector 400.

Each of the first lower damper 321 and the second lower damper 322 may include a material configuring the lower damper 320 disclosed in FIG. 1. For example, the first lower damper 321 and the second lower damper 322 may include the same material. As another example, each of the first lower damper 321 and the second lower damper 322 may include a different material which is at least some among the material configuring the lower damper 320 disclosed in FIG. 1.

Each of the first upper damper 331 and the second upper damper 332 may include the material configuring the upper damper 330 disclosed in FIG. 1. For example, the first upper damper 331 and the second upper damper 332 may include the same material. As another example, each of the first upper damper 331 and the second upper damper 332 may include a different material which is at least some among the material configuring the upper damper 330 disclosed in FIG. 1.

As the vibration absorbing unit 300 includes the supporter 310, the first lower damper 321, the second lower damper 322, the first upper damper 331, and the second upper damper 332, the vibration absorbing unit 300 may absorb the vibration transferred to the connector 400, and may prevent a rotation or a flip of the connector holder 410.

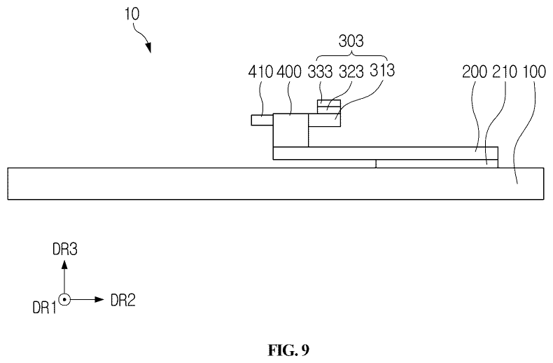

FIG. 9 is a side view illustrating a display device according to still another embodiment. The vibration absorbing unit 300 of the display device in FIG. 9 has a different configuration from that of the vibration absorbing unit 300 of the display device in FIG. 1, and thus, the same components as those described above will be briefly described or omitted.

Referring to FIG. 9, a vibration absorbing unit 303 may be disposed on a side surface of the connector 400. The vibration absorbing unit 303 may be disposed between the connector 400 and the adhesive member 210 on a plane. The vibration absorbing unit 303 may not overlap the adhesive member 210 in the third direction DR3 or the thickness direction. The vibration absorbing unit 303 may be spaced apart from the adhesive member 210 in the second direction DR2.

The vibration absorbing unit 303 may include at least one supporter 313, a lower damper 323, and an upper damper 333. The at least one supporter 313 may be disposed on a side surface of the connector 400. The supporter 313 may be disposed on the first side surface of the connector 400, and the connector holder 410 may be disposed on the second side surface opposite the first side surface of the connector 400. At least one supporter 313 may be disposed below a first side of the lower damper 323, or may be disposed below a second side opposite the first side of the lower damper 323.

The lower damper 323 may be disposed on the at least one supporter 313. The upper damper 333 may be disposed on the lower damper 323. A material configuring the upper damper 333 may be different from a material configuring the lower damper 323. As the vibration absorbing unit 303 includes the lower damper 323 and the upper damper 333, each of which including a different material, the vibration absorbing unit 303 may reduce the resonant frequency and absorb vibration transferred to the connector 400.

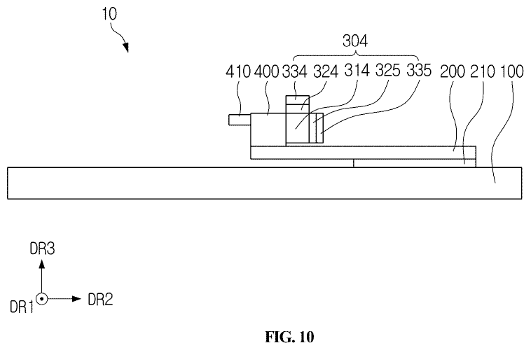

FIG. 10 is a side view illustrating a display device according to still another embodiment. The vibration absorbing unit 304 of the display device 10 in FIG. 10 has a different configuration from that of the vibration absorbing unit 300 of the display device in FIG. 1, and thus, the same components as those described above will be briefly described or omitted.

Referring to FIG. 10, the vibration absorbing unit 304 may be disposed on a side surface of the connector 400. The vibration absorbing unit 304 may be disposed between the connector 400 and the adhesive member 210 on a plane. The vibration absorbing unit 304 may not overlap the adhesive member 210 in the third direction DR3 or the thickness direction. The vibration absorbing unit 304 may be spaced apart from the adhesive member 210 in the second direction DR2.

The vibration absorbing unit 304 may include a supporter 314, a first lower damper 324, and a second lower damper 325, a first upper damper 334, and a second upper damper 335. The at least one supporter 314 may be disposed on a side surface of the connector 400. The at least one supporter 314 may be disposed below a first side of the first lower damper 324, or below a second side opposite the first side of the first lower damper 324. The at least one supporter 314 may be disposed below a left side or a right side of the first lower damper 324, and may support the lower damper 320. The supporter 314 may support the first lower damper 324 in the third direction DR3. The supporter 314 may be disposed on a side surface of the second lower damper 325. The supporter 314 may support the second lower damper 325 in the second direction DR2.

As another example, the supporter 314 may support a left side or a right side of the first lower damper 324 and the second lower damper 325 by reflecting the embodiment of FIG. 5.

The first lower damper 324 may be disposed on the at least one supporter 314. The first upper damper 334 may be disposed on the first lower damper 324. A material configuring the first upper damper 334 may be different from a material configuring the first lower damper 324. As the vibration absorbing unit 304 includes the first lower damper 324 and the first upper damper 334, each of which including a different material, the vibration absorbing unit 304 may reduce the resonant frequency and absorb vibration transferred to the connector 400.

The second lower damper 325 may be disposed on a side surface of the at least one supporter 314. The second upper damper 335 may be disposed on the second lower damper 325. A material configuring the second upper damper 335 may be different from a material configuring the second lower damper 325. As the vibration absorbing unit 304 includes the second lower damper 325 and the second upper damper 335, each of which including a different material, the vibration absorbing unit 304 may reduce the resonant frequency and absorb vibration transferred to the connector 400.

Each of the first lower damper 324 and the second lower damper 325 may include a material configuring the lower damper 320 disclosed in FIG. 1. For example, the first lower damper 324 and the second lower damper 325 may include the same material. As another example, each of the first lower damper 324 and the second lower damper 325 may include a different material which is at least some among the material configuring the lower damper 320 disclosed in FIG. 1.

Each of the first upper damper 334 and the second upper damper 335 may include the material configuring the upper damper 330 disclosed in FIG. 1. For example, the first upper damper 334 and the second upper damper 335 may include the same material. As another example, each of the first upper damper 334 and the second upper damper 335 may include a different material which is at least some among the material configuring the upper damper 330 disclosed in FIG. 1.

As the vibration absorbing unit 304 includes the supporter 314, the first lower damper 324, the second lower damper 325, the first upper damper 334, and the second upper damper 335, the vibration absorbing unit 304 may absorb the vibration transferred to the connector 400, and may prevent a rotation or a flip of the connector holder 410.

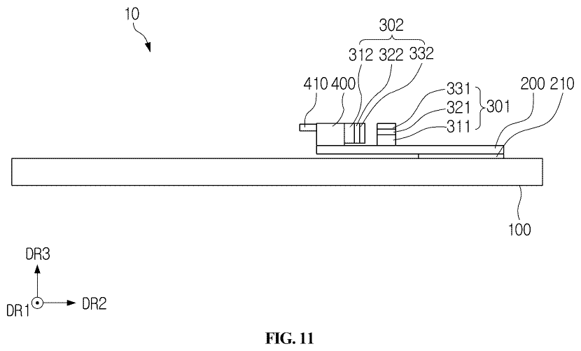

FIG. 11 is a side view illustrating a display device according to still another embodiment. A first vibration absorbing unit 301 and a second vibration absorbing unit 302 of the display device in FIG. 11 have a different configuration from that of the vibration absorbing unit 300 of the display device in FIG. 1, and thus, the same components as those described above will be briefly described or omitted.

Referring to FIG. 11, the display device 10 may include the display panel 100, the circuit board 200, the first vibration absorbing unit 301, the second vibration absorbing unit 302, and the connector 400.

The first vibration absorbing unit 301 may be disposed on one surface of the circuit board 200. The first vibration absorbing unit 301 may be disposed between the connector 400 and the adhesive member 210 on a plane. The first vibration absorbing unit 301 may be disposed between the second vibration absorbing unit 302 and the adhesive member 210 on a plane. The first vibration absorbing unit 301 may not overlap the adhesive member 210 in the third direction DR3 or the thickness direction. The first vibration absorbing unit 301 may be spaced apart from the adhesive member 210 in the second direction DR2.

The first vibration absorbing unit 301 may include at least one first supporter 311, a first lower damper 321, and a first upper damper 331. The at least one first supporter 311 may be disposed on one surface of the circuit board 200. The at least one supporter 311 may be disposed below a first side of the first lower damper 321, or below a second side opposite the first side of the first lower damper 321.

The first lower damper 321 may be disposed on the at least one first supporter 311. The first lower damper 321 may include a long side in the first direction DR1, a short side in the second direction DR2, and a thickness in the third direction DR3. A length of the first lower damper 321 in the first direction DR1 may correspond to the length of the connector 400 in the first direction DR1. A material configuring the first lower damper 321 may be different from a material configuring the first upper damper 331.

The first upper damper 331 may be disposed on the first lower damper 321. A planar shape and a size of the first upper damper 331 may be substantially the same as a planar shape and a size of the first lower damper 321, however, the planar shape of the first upper damper 331 is not limited thereto. The first upper damper 331 may include a long side in the first direction DR1, a short side in the second direction DR2, and a thickness in the third direction DR3. A length of the first upper damper 331 in the first direction DR1 may correspond to the length of the connector 400 in the first direction DR1. A material configuring the first upper damper 331 may be different from a material configuring the first lower damper 321. As the first vibration absorbing unit 301 includes the first lower damper 321 and the first upper damper 331, each of which including a different material, the first vibration absorbing unit 301 may reduce the resonant frequency and absorb vibration transferred to the connector 400.

The second vibration absorbing unit 302 may be disposed on a side surface of the connector 400. The second vibration absorbing unit 302 may be disposed between the connector 400 and the adhesive member 210 on a plane. The second vibration absorbing unit 302 may be disposed between the connector 400 and the first vibration absorbing unit 301 on a plane. The second vibration absorbing unit 302 may not overlap the adhesive member 210 in the third direction DR3 or the thickness direction. The second vibration absorbing unit 302 may be spaced apart from the adhesive member 210 in the second direction DR2.

The second vibration absorbing unit 302 may include at least one second supporter 312, a second lower damper 322, and a second upper damper 332. The at least one second supporter 312 may be disposed on a side surface of the connector 400. The second supporter 312 may be disposed on the first side surface of the connector 400, and the connector holder 410 may be disposed on the second side surface opposite the first side surface of the connector 400. The second lower damper 322 may be disposed on a first side surface of the second supporter 312, and the connector 400 may be disposed on a second side surface opposite the first side surface of the second supporter 312. The at least one second supporter 312 may support the second lower damper 322 in the second direction DR2.

The second lower damper 322 may be disposed on a side surface of the second supporter 312. A first side surface of the second supporter 312 may support the second lower damper 322 in the second direction DR2, and a second side surface of the second supporter 312 opposite the first side surface thereof may be supported by the connector 400. The second lower damper 322 may include a long side in the first direction DR1, a short side in the third direction DR3, and a thickness in the second direction DR2. A length of the second lower damper 322 in the first direction DR1 may correspond to the length of the connector 400 in the first direction DR1. A material configuring the second lower damper 322 may be different from a material configuring the second upper damper 332.

The second upper damper 332 may be disposed on a side surface of the second lower damper 322. A planar shape and a size of the second upper damper 332 may be substantially the same as a planar shape and a size of the second lower damper 322, however, the planar shape of the second upper damper 332 is not limited thereto. The second upper damper 322 may include a long side in the first direction DR1, a short side in the third direction DR3, and a thickness in the second direction DR2. A length of the second upper damper 332 in the first direction DR1 may correspond to the length of the connector 400 in the first direction DR1. A material configuring the second upper damper 332 may be different from a material configuring the second lower damper 322. As the second vibration absorbing unit 302 includes the second lower damper 322 and the second upper damper 332, each of which including a different material, the second vibration absorbing unit 302 may reduce the resonant frequency and absorb vibration transferred to the connector 400.

Each of the first supporter 311 and the second supporter 312 may include a material configuring the supporter 310 disclosed in FIG. 1. For example, the first supporter 311 and the second supporter 312 may include the same material. As another example, each of the first supporter 311 and the second supporter 312 may include a different material which is at least some among the material configuring the supporter 310 disclosed in FIG. 1.

Each of the first lower damper 321 and the second lower damper 322 may include the material configuring the lower damper 320 disclosed in FIG. 1. For example, the first lower damper 321 and the second lower damper 322 may include the same material. As another example, each of the first lower damper 321 and the second lower damper 322 may include a different material which is at least some among the material configuring the lower damper 320 disclosed in FIG. 1.

Each of the first upper damper 331 and the second upper damper 332 may include the material configuring the upper damper 330 disclosed in FIG. 1. For example, the first upper damper 331 and the second upper damper 332 may include the same material. As another example, each of the first upper damper 331 and the second upper damper 332 may include a different material which is at least some among the material configuring the upper damper 330 disclosed in FIG. 1.

Therefore, as the display device 10 includes the first vibration absorbing unit 301 disposed on one surface of the circuit board 200, and the second vibration absorbing unit 302 disposed on the side surface of the connector 400, the first vibration absorbing unit 301 and the second vibration absorbing unit 302 may absorb the vibration transferred to the connector 400, and may prevent a rotation or a flip of the connector holder 410, thereby preventing damages to other adjacent display panels 100.

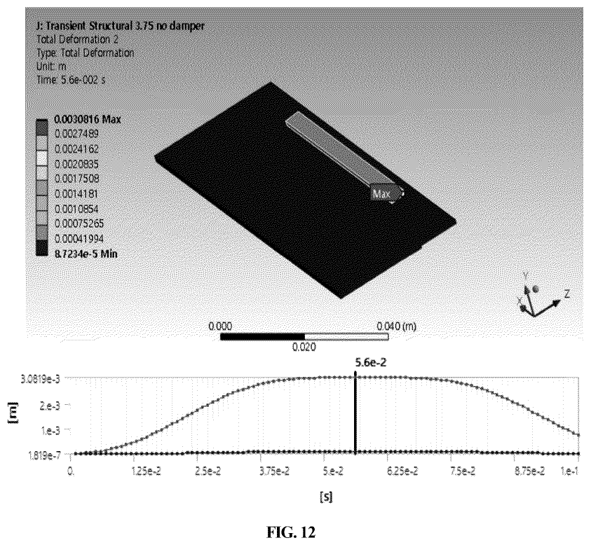

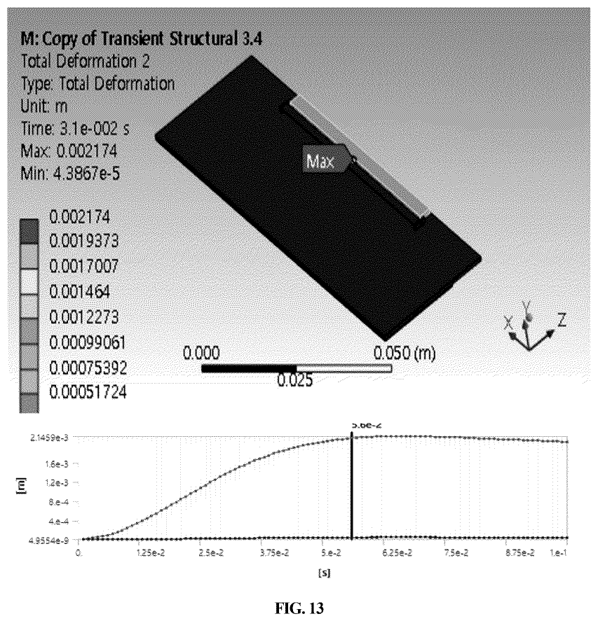

FIG. 12 is a view illustrating an intensity of a vibration energy in a display device in which the vibration absorbing unit is omitted, and FIG. 13 is a view illustrating an intensity of a vibration energy in a display device in which the vibration absorbing unit is included.

The display device in FIG. 12 corresponds to a display device for comparison, and the display device in FIG. 13 corresponds to the display device illustrated in FIG. 1.

The display device 10 in FIG. 12 does not include the vibration absorbing unit, and thus, the vibration in the display panel 100 may be transferred to the connector 400 through the adhesive member 210 and the circuit board 200. For example, in the transport process of the plurality of display panels 100, a maximum intensity of the vibration energy transferred to the connector 400 may be approximately 3.08 mm.

In FIG. 13, the display device 10 may include the vibration absorbing unit 300, and the vibration absorbing unit 300 may be disposed in the vibration transfer path of the display panel 100 and may absorb vibration transferred to the connector 400. For example, in the transport process of the plurality of display panels 100, the maximum intensity of the vibration energy transferred to the connector 400 may be approximately 2.14 mm. Therefore, as the display device 10 includes the first vibration absorbing unit 300, the first vibration absorbing unit 300 may absorb the vibration transferred to the connector 400, and may prevent a rotation or a flip of the connector holder 410, thereby preventing damages to other adjacent display panels 100.

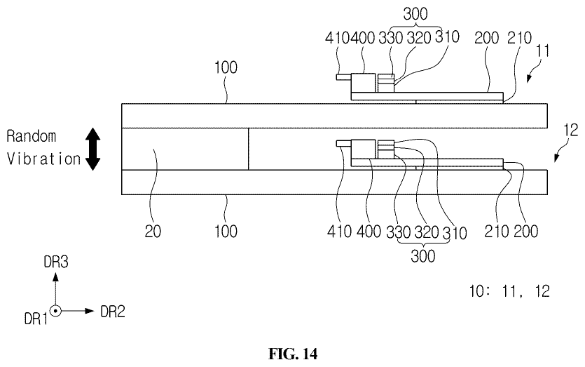

FIG. 14 is a view illustrating the transport process of the plurality of display devices.

Referring to FIG. 14, the plurality of display devices 10 may be loaded on a transportation device (not illustrated) and may be transported in the second direction DR2, or in a direction opposite the second direction DR2. The transportation device may include a supporting portion 20. The supporting portion 20 may be disposed between the display devices 10, space the display devices 10 from each other at a certain interval, and may fix and support the display devices 10.

In the process of transporting first and second display devices 11 and 12 in the second direction DR2, or in the direction opposite the second direction DR2, the display panel 100 of each of the first and second display devices 11 and 12 may vibrate in the third direction DR3. The vibration of the display panel 100 in the third direction DR3 may be transferred to the adhesive member 210 and the circuit board 200, and may be transferred to the vibration absorbing unit 300 through the vibration of the circuit board 200 in the second direction DR2, or in the direction opposite the second direction DR2. As the vibration absorbing unit 300 does not overlap the adhesive member 210 in the thickness direction, the vibration of the display panel 100 in the third direction DR3 may not be directly transferred through the adhesive member 210. A resonant frequency of the vibration absorbing unit 300 may be the same as or lower than a resonant frequency of rotation of the connector holder 410.

In the process of transporting the first and second display devices 11 and 12, when the vibration of the second display device 12 transferred from the display panel 100 reaches the connector 400, the connector holder 410 may rotate and damage the first display device 11 adjacent thereto. Therefore, as the vibration absorbing unit 300 of the second display device 12 is disposed in the vibration transfer path of the display panel 100, the vibration absorbing unit 300 may absorb the vibration transferred to the connector 400, and may prevent a damage to other adjacent first display device 11 by preventing a rotation or a flip of the connector holder 410.

The display device 10 according to various embodiments of the present disclosure may be described as below.

One embodiment is a display device, including: a display panel including a plurality of pixels and configured to display an image; a circuit board attached to one surface of the display panel through an adhesive member; a vibration absorbing unit disposed on one surface of the circuit board, spaced apart from the adhesive member on a plane and configured to absorb vibration; and a connector disposed on one surface of the circuit board, and the vibration absorbing unit may include: at least one supporter disposed on one surface of the circuit board; a lower damper disposed on the at least one supporter; and an upper damper disposed on the lower damper.

In a display device according to various embodiments of the present disclosure, the circuit board may include: a first portion attached to the adhesive member; a second portion having an arrangement of the vibration absorbing unit; and a third portion having an arrangement of the connector, and the second portion and the third portion of the circuit board may not be attached to the adhesive member and may be spaced apart from the one surface of the display panel.

In a display device according to various embodiments of the present disclosure, the second portion of the circuit board may be disposed between the first portion and the third portion.

In a display device according to various embodiments of the present disclosure, the display device may further include: a connector holder having one end fixed to the connector and another end configured to rotate about the one end.

In a display device according to various embodiments of the present disclosure, the supporter may include a plastic material such as polycarbonate (PC), polyimide (PI), polyethylene naphthalate (PEN), polyethylene terephthalate (PET), polyethersulfone (PES), polyacrylate (PAR), or a fiber reinforced plastic.

In a display device according to various embodiments of the present disclosure, the lower damper may include a metal material.

In a display device according to various embodiments of the present disclosure, the lower damper may include at least one among aluminum (Al), molybdenum (Mo), chrome (Cr), gold (Au), silver (Ag), titanium (Ti), nickel (Ni), palladium (Pd), indium (In), neodymium (Nd), and copper (Cu).

In a display device according to various embodiments of the present disclosure, the upper damper may include at least one among a polymer, silicon, and rubber.

In a display device according to various embodiments of the present disclosure, the upper damper may include at least one among ultra-high-molecular-weight polyethylene (UHMWPE), high-density polyethylene (HDPE), polypropylene (PP), polyetherimide (PEI), fluorinated ethylene propylene (FEP), polytetrafluoroethylene (PTFE), methyl fluoroacetate (MFA), perfluoroalkoxy alkane (PFA).

In a display device according to various embodiments of the present disclosure, the at least one supporter may include a first supporter and a second supporter, and the first supporter supports a lower portion of a first side of the lower damper, and the second supporter may support a lower portion of a second side opposite the first side of the lower damper.

In a display device according to various embodiments of the present disclosure, the at least one supporter may include a first supporter, and the first supporter may support a lower portion of one side of the lower damper.

In a display device according to various embodiments of the present disclosure, the vibration absorbing unit may further include: a second lower damper disposed on a side surface of the at least one supporter; and a second upper damper disposed on the second lower damper.

In a display device according to various embodiments of the present disclosure, a first material of the lower damper and a third material of the second lower damper are same materials, and a second material of the upper damper and a fourth material of the second upper damper are same materials.

In a display device according to various embodiments of the present disclosure, a first material of the lower damper and a third material of the second lower damper are materials different from each other, or a second material of the upper damper and a fourth material of the second upper damper are materials different from each other.

In a display device according to various embodiments of the present disclosure, a first side surface of the at least one supporter may support the second lower damper, and a second side surface opposite the first side surface may face the connector.

Another embodiment is a display device, including: a display panel including a plurality of pixels and configured to display an image; a circuit board attached to one surface of the display panel through an adhesive member; a connector disposed on one surface of the circuit board; and a vibration absorbing unit disposed on one surface of the connector, spaced apart from the adhesive member on a plane and configured to absorb vibration, and the vibration absorbing unit may include: at least one supporter disposed on a side surface of the connector; a lower damper disposed on the at least one supporter; and an upper damper disposed on the lower damper.

In a display device according to various embodiments of the present disclosure, the connector may include: a first side surface which supports the at least one supporter; and a second side surface opposite the first side surface, and the display device may further include: a connector holder disposed on the second side surface of the connector and having one end fixed to the connector and another end configured to rotate about the one end.

In a display device according to various embodiments of the present disclosure, the vibration absorbing unit may further include: a second lower damper disposed on a side surface of the at least one supporter; and a second upper damper disposed on the second lower damper.

In a display device according to various embodiments of the present disclosure, the connector may include: a first side surface which supports the at least one supporter; and a second side surface opposite the first side surface, and the display device may further include: a connector holder disposed on the second side surface of the connector and having one end fixed to the connector and another end configured to rotate about the one end.

In a display device according to various embodiments of the present disclosure, the display device may further include: a second vibration absorbing unit disposed on a side surface of the connector and configured to absorb vibration.

In a display device according to various embodiments of the present disclosure, the second vibration absorbing unit may include: at least one second supporter disposed on the side surface of the connector; a second lower damper disposed on a side surface of the at least one second supporter; and a second upper damper disposed on a side surface of the second lower damper.

Another embodiment is a display device, including: a display panel including a plurality of pixels, wherein the display device is configured to display an image; a circuit board disposed on the display panel; an adhesive member that attaches a portion of the circuit board to the display panel; a vibration absorbing unit disposed above the circuit board; a connector disposed on one surface of the circuit board; and a connector holder attached to one surface of the connector. In some embodiments, the connector holder is configured to electrically connect the connector to a control circuit. In some embodiments, the adhesive member, the circuit board, the vibration absorbing unit, and the connector are sequentially arranged in a first direction.

In a display device according to various embodiments of the present disclosure, the vibration absorbing unit includes: at least one supporter disposed above the circuit board; at least one lower damper disposed on the at least one supporter; and at least one upper damper disposed on the at least one lower damper. In some embodiments, a material of the at least one supporter, a material of the at least one lower damper, and a material of the at least one upper damper are different.

In a display device according to various embodiments of the present disclosure, the at least one supporter comprises a plastic material; the at least one lower damper comprises a metal material; and the at least one upper dumper comprises at least one of a polymer, silicon, and rubber.

In a display device according to various embodiments of the present disclosure, the vibration absorbing unit is attached to the circuit board.

In a display device according to various embodiments of the present disclosure, vibration absorbing unit is attached to the connector.

The present disclosure has been described in more detail with reference to the exemplary embodiments, but the present disclosure is not limited to the exemplary embodiments. It will be apparent to those skilled in the art that various modifications can be made without departing from the technical sprit of the disclosure. Accordingly, the exemplary embodiments disclosed in the present disclosure are used not to limit but to describe the technical spirit of the present disclosure, and the technical spirit of the present disclosure is not limited to the exemplary embodiments. Therefore, the exemplary embodiments described above are considered in all respects to be illustrative and not restrictive. The protection scope of the present disclosure must be interpreted by the appended claims and it should be interpreted that all technical spirits within a scope equivalent thereto are included in the appended claims of the present disclosure.

What is claimed is:

1. A display device, comprising:
a display panel including a plurality of pixels and configured to display an image;
a circuit board attached to one surface of the display panel through an adhesive member;
a vibration absorbing unit disposed on one surface of the circuit board, spaced apart from the adhesive member on a plane and configured to absorb vibration; and
a connector disposed on one surface of the circuit board,
wherein the vibration absorbing unit comprises:
at least one supporter disposed on one surface of the circuit board;
a lower damper disposed on the at least one supporter; and
an upper damper disposed on the lower damper.

2. The display device of claim 1,
wherein the circuit board comprises:
a first portion attached to the adhesive member;
a second portion having an arrangement of the vibration absorbing unit; and
a third portion having an arrangement of the connector,
wherein the second portion of the circuit board and the third portion of the circuit board are not attached to the adhesive member, and wherein the second portion of the circuit board and the third portion of the circuit board are spaced apart from the one surface of the display panel.

3. The display device of claim 2,
wherein the second portion of the circuit board is disposed between the first portion and the third portion.

4. The display device of claim 1, further comprising:
a connector holder having one end fixed to the connector and another end configured to rotate about the one end.

5. The display device of claim 1,
wherein the at least one supporter comprises a plastic material selected from polycarbonate (PC), polyimide (PI), polyethylene naphthalate (PEN), polyethylene terephthalate (PET), polyethersulfone (PES), polyacrylate (PAR), and a fiber reinforced plastic.

6. The display device of claim 1,
wherein the lower damper comprises a metal material,
wherein the lower damper comprises at least one of aluminum (Al), molybdenum (Mo), chrome (Cr), gold (Au), silver (Ag), titanium (Ti), nickel (Ni), palladium (Pd), indium (In), neodymium (Nd), and copper (Cu).

7. The display device of claim 1,
wherein the upper damper comprises at least one of a polymer, silicon, and rubber,
wherein the upper damper comprises at least one of ultra-high-molecular-weight polyethylene (UHMWPE), high-density polyethylene (HDPE), polypropylene (PP), polyetherimide (PEI), fluorinated ethylene propylene (FEP), polytetrafluoroethylene (PTFE), methyl fluoroacetate (MFA), and perfluoroalkoxy alkane (PFA).

8. The display device of claim 1,
wherein the at least one supporter comprises a first supporter and a second supporter, and
wherein the first supporter supports a lower portion of a first side of the lower damper, and the second supporter supports a lower portion of a second side opposite the first side of the lower damper.

9. The display device of claim 1,
wherein the at least one supporter comprises a first supporter, and
wherein the first supporter supports a lower portion of one side of the lower damper.

10. The display device of claim 1,
wherein the vibration absorbing unit further comprises:
a second lower damper disposed on a side surface of the at least one supporter; and
a second upper damper disposed on the second lower damper.

11. The display device of claim 10,
wherein a first material of the lower damper and a third material of the second lower damper are same materials, and wherein a second material of the upper damper and a fourth material of the second upper damper are same materials.

12. The display device of claim 10,
wherein a first material of the lower damper and a third material of the second lower damper are materials different from each other, or wherein a second material of the upper damper and a fourth material of the second upper damper are materials different from each other.

13. The display device of claim 10,
wherein a first side surface of the at least one supporter supports the second lower damper, and wherein a second side surface opposite the first side surface faces the connector.

14. A display device, comprising:
a display panel comprising a plurality of pixels, wherein the display panel is configured to display an image;
a circuit board attached to one surface of the display panel through an adhesive member;
a connector disposed on one surface of the circuit board; and
a vibration absorbing unit disposed on one surface of the connector, wherein the vibration absorbing unit is spaced apart from the adhesive member on a plane, and wherein the vibration absorbing unit is configured to absorb vibration,
wherein the vibration absorbing unit comprises:
at least one supporter disposed on a side surface of the connector;
a lower damper disposed on the at least one supporter; and
an upper damper disposed on the lower damper.

15. The display device of claim 14,
wherein the connector comprises:
a first side surface which supports the at least one supporter; and
a second side surface opposite the first side surface, and
wherein the display device further comprises:
a connector holder disposed on the second side surface of the connector and having one end fixed to the connector and another end configured to rotate about the one end.

16. The display device of claim 14,
wherein the vibration absorbing unit further comprises:
a second lower damper disposed on a side surface of the at least one supporter; and
a second upper damper disposed on the second lower damper.

17. The display device of claim 16,
wherein the connector comprises:
a first side surface which supports the at least one supporter; and
a second side surface opposite the first side surface,
wherein the display device further comprises:
a connector holder disposed on the second side surface of the connector and having one end fixed to the connector and another end configured to rotate about the one end.

18. The display device of claim 14, further comprising:
a second vibration absorbing unit disposed on a side surface of the connector and configured to absorb vibration.

19. The display device of claim 18,
wherein the second vibration absorbing unit comprises:
at least one second supporter disposed on the side surface of the connector;
a second lower damper disposed on a side surface of the at least one second supporter; and
a second upper damper disposed on a side surface of the second lower damper.

20. A display device, comprising:
a display panel including a plurality of pixels, wherein the display device is configured to display an image;
a circuit board disposed on the display panel;
an adhesive member that attaches a portion of the circuit board to the display panel;
a vibration absorbing unit disposed above the circuit board;
a connector disposed on one surface of the circuit board; and
a connector holder attached to one surface of the connector,
wherein the connector holder is configured to electrically connect the connector to a control circuit, and
wherein the adhesive member, the circuit board, the vibration absorbing unit, and the connector are sequentially arranged along a first direction.
